(19) United States
(12) Patent Application Publication
(10) Pub. No.: US 2010/0325513 A1
(43) Pub. Date: Dec. 23, 2010

(54) INTEGRATED CONTROL ELECTRONICS (ICE) FOR A HOLOGRAPHIC STORAGE SYSTEM

(76) Inventors: PETER DONEGAN, MONTCLAIR, NJ (US); MARLON KASPRZYK, WINFIELD, IL (US); GLENN A. GLADNEY, MANALAPAN, NJ (US)

Correspondence Address: KNOBLE, YOSHIDA & DUNLEAVY, EIGHT PENN CENTER, SUITE 1350, 1628 JOHN F KENNEDY BLVD, PHILADELPHIA, PA, 19103, US

(21) Appl. No.: 12/818,553

(22) Filed: Jun. 18, 2010

Related U.S. Application Data
(60) Provisional application No. 61/218,241, filed on Jun. 18, 2009.

(51) Int. Cl. G11C 13/04; H03M 13/05; G06F 11/10

(52) U.S. Cl. 714/752; 365/125; 365/216; 714/E11.032

(57) ABSTRACT

Integrated control electronics for a holographic storage system that is adapted for controlling read/write logic in a holographic storage device. The control electronics may control beam steering devices, SLM devices, shutters, optical sensor arrays and lasers.

This Application claims the benefit of U.S. Provisional Patent No. 61/218,241 filed on Jun. 18, 2009, the contents of which are incorporated by reference.

### BACKGROUND OF THE INVENTION

1. Field of the Invention

The present invention is directed to holographic storage systems. In particular the invention is directed to integrated control electronics for holographic storage systems.

2. Description of the Related Technology

Currently there are no integrated control electronics (ICE) for holographic storage systems that employ re-write and erase steps. Additionally, there are no volumetric media integrated controls and electronics for read and write steps in a holographic storage system. Furthermore, there is no standard commercial data protocol interface for holographic storage.

Therefore, there is a need in the field for ICE active optical devices for read/re-write and erase in a holographic system. A need also exists for electronic control of optical devices such as lasers, acoustic-optical and electro-optic modulators and electrical devices, such as DMD, MEMs Dual-Axis mirror, Sensor Array, and SATA II that may be used in a holographic storage system. A need also exists for improved timing, sequencing, shuttering and maintenance including thermo-electric cooling.

### SUMMARY OF THE INVENTION

An object of the present invention is integrated control electronics for use in a holographic storage system.

Another object of the present invention is a method of using integrated control electronics in a holographic storage system.

An aspect of the present invention may be an integrated control electronics for a holographic storage system comprising: a Command Sequencer for receiving commands from a system interface; a Write Control Logic for encoding write data into a data beam; a Page Control Logic for controlling a beam steering device for directing a reference beam; and an Optical Sensor Array Interface for sending control signals to an optical sensor array.

Another aspect of the present invention may be a method for using integrated control electronics in a holographic storage system comprising the steps of: receiving commands via a system interface at a Command Sequencer; operating a beam steering device using Page Control Logic; operating a Spatial Light Modulator (SLM) using Write Control Logic; operating an Optical Sensor Array Interface for sending control signals to an Optical Sensor Array; and wherein data is written to and read from a photorefractive crystal using the steps of operating the beam steering device; operating the spatial light modulator and operating the Optical Sensor Array.

Still yet another aspect of the present invention may be an integrated control electronics for a holographic storage system comprising: a field programmable gate array adapted for providing Write Control Logic for encoding write data into a data beam; wherein the field programmable gate array is programmed to provide a Command Sequencer for receiving commands from a system interface; wherein the field programmable gate array is programmed to provide Write Control Logic for encoding write data into a data beam; wherein the field programmable gate array is programmed to provide Page Control Logic for controlling a beam steering device for directing a reference beam; and wherein the field programmable gate array is programmed to provide an Optical Sensor Array Interface for sending control signals to an optical sensor array.

These and various other advantages features of novelty that characterize the invention are pointed out with particularity in the claims annexed hereto and forming a part hereof. However, for a better understanding of the invention, its advantages, and the objects obtained by its use, reference should be made to the drawings which form a further part hereof, and to the accompanying descriptive matter, in which there is illustrated and described a preferred embodiment of the invention.

### BRIEF DESCRIPTION OF THE DRAWINGS

FIG. 1 is a block diagram of integrated control electronics for a holographic storage system, made in accordance with an embodiment of the present invention.

FIG. 2 is a block diagram showing the logic used with the control electronics shown in FIG. 1.

FIG. 3 is a flow chart showing a method of operating the control electronics in accordance with an embodiment of the present invention.

### DETAILED DESCRIPTION OF THE PREFERRED EMBODIMENT(S)

A Spatial Light Modulator (SLM) 28 may be a Digital Light Processor (DLP) that may be comprised of an array of micro-mirrors 11. Each micro-mirror 11 may be individually controlled and represent one unique data point per page. The micro-mirrors 11 are switched between two positions. A first position that reflects the data beam into a crystal, hereinafter referred to as the ON position and a second position that reflects the data beam away from the crystal, hereinafter referred to as the OFF position. The crystal may be a photorefractive crystal such as LiNbO₃. When a micro-mirror 11 is in the ON position, the reflected light from that micro-mirror 11 combines with the reference beam to write a pixel into the crystal. The intensity of the pixel is determined by the amount of time that the micro-mirror 11 is in the ON position. The use of different pixel intensities allows the invention to use two data modes, Binary or Grayscale. In Binary mode, each pixel represents one logical bit of information. In Grayscale mode, each pixel can represent several binary bits, depending on the intensity of the pixel. Each illumination level is assigned to logical one or logical zero.

The intensity of a pixel in Grayscale is a function of how long the photorefractive crystal is exposed to laser input. The micro-mirrors 11 (on the MEMS SLM) corresponding to illuminated pixels are set to the ON position while the reference beam also illuminates the crystal. After a predetermined period of time, the micro-mirrors 11 corresponding to lowest grayscale intensity are set to the OFF position, while the remaining ones for higher grayscale intensity are left ON. This process may be repeated until all appropriate grayscale levels have been further illuminated, and until the highest grayscale levels have been reached. Each illumination level is assigned a different combination of bits.

Grayscale Commands may be given in one of two ways. One way may be to update the data pattern on the MEMS SLM 28 while the Read/Write Pulse and Data Pulse are still being asserted. The alternative method is to re-load the SLM 28 after these pulses have finished asserting; then re-asserting them after the SLM 28 is re-loaded.

If the photorefractive data storage crystal requires bulk erasure to remove all data previously stored within it, the entire crystal may be flooded with unpolarized light at a range of angles, which includes the whole range of address angles. This bulk erasure procedure may be accomplished by using a bulk erase laser 7, which may operate at a wavelength of 532 nanometers or at a shorter wavelength, which is similar to the operation of the laser 9. Alternatively, an incoherent light source may be used. In either case, bulk erasure is accomplished by directing light from a separate source onto the photorefractive crystal before it is used for subsequent data recording. Bulk erasure may take up to, or on average be 10 minutes.

If the photorefractive crystal requires selective erasure of only a portion of a single data page that has been previously written into it, an electro-optic modulator in the reference beam is operated at a voltage that will shift its phase by 180° with respect to how it was operated during original writing while the voltage applied to the electro-optic modulator in the data beam is kept at its original value. From known information preserved for the data that was recorded for the portion of the page that now requires erasure, the individual micro-mirrors 11 on the SLM 28 are set to the ON position and selective erasure is performed under this 180° phase shifted condition.

In binary mode, the micro-mirrors 11 for the pixels that are to be illuminated are set to the ON position, and the crystal is again illuminated by the reference beam.

In both binary and grayscale modes, the section to be written to is first erased by writing the Erase Pattern of the maximum grayscale value, or all “1”s for the binary case to that portion of the crystal, followed by re-writing this same erase pattern with either the reference beam or the data beam phase (but not both) phase-shifted by 180 degrees. The intensity of the data and/or the reference beams while writing the Erase Pattern during erasure may or may not be the same as when writing data.

The micro-mirrors 11 for the pixels that are to be illuminated are set to the ON position, and the crystal is again illuminated by the reference beam. After a pre-determined period of time, the micro-mirrors 11 corresponding to the lowest intensity are set to the OFF position, while the rest remain ON. This is repeated until the various pixels are set to the appropriate illumination level. Each illumination level is assigned to a different combination of bits.

The current design uses the Cypress LUPA 1300-2. The 10-bit pixels are downloaded in 12 serial data streams with a sync channel. The Optical Sensor Array Interface then aligns the pixels. The pixels are then fed into the Threshold Detector where they are first converted into bits and then concatenated into bytes. For the initial system, there are 2 levels and 1 bit.

For gray scale systems, 4 levels will be output as 2 bits; 16 levels as 4 bits, etc. The bytes are then sent to the Forward Error Correction (FEC) Decode Logic where any errors that were introduced in writing, storing or reading the data are removed. The data is then sent to the System Interface (which is a SATA interface in the current configuration) where it is then sent to the Host Computer.

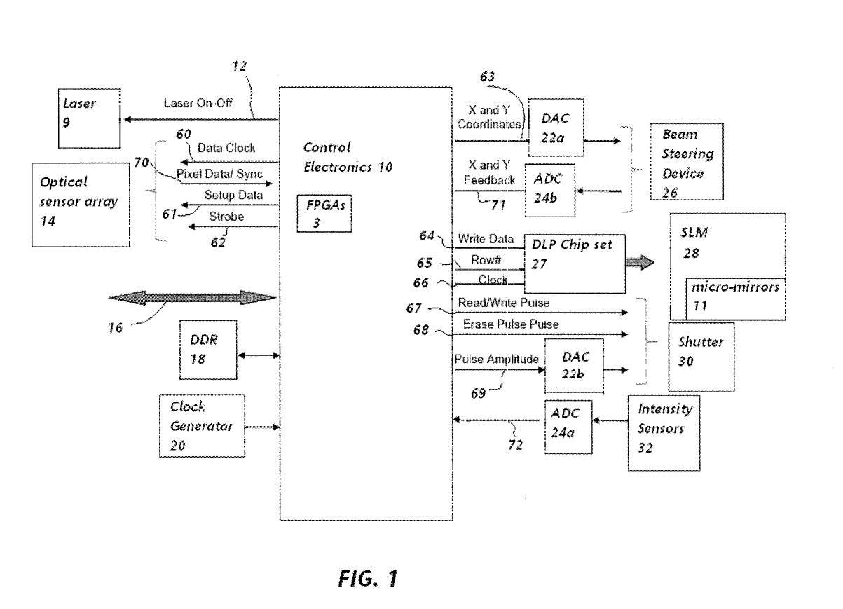

FIG. 1 shows a diagram of the integrated control electronics used for reading and writing to the holographic storage system and in particular the spatial light modulator data/control. The central block is the control electronics 10, which may be comprised of one or more field programmable gate arrays (FPGAs) 3.

The control electronics 10 transmit laser on-off signals 12 to a laser 9. The laser 9 is used to modify the photorefractive data storage crystal.

Transmitted to an optical sensor array 14 from the control electronics are the data clock signals 60. Also transmitted to the optical sensor array 14 are the setup data signals 61 and the strobe data 62. Transmitted from the optical sensor array 14 to the control electronics 10 are the pixel data/sync signals 70.

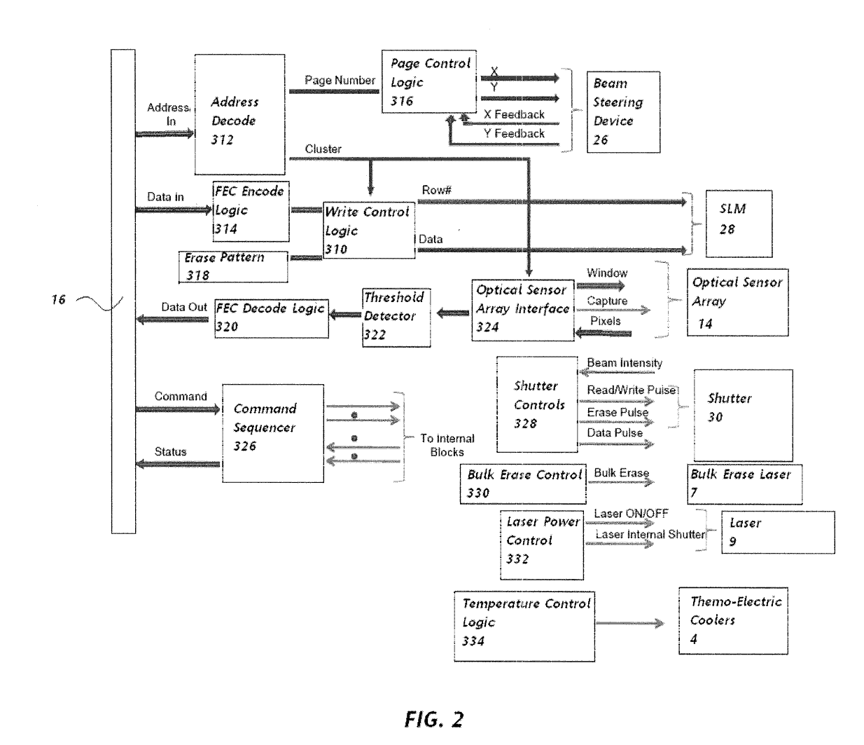

Also shown in the diagram of FIG. 1 is the system interface 16. There are various cores that may be used for the system interface 16, SATA, PCI Express, PCI, Fibre Channel and other system interfaces available for the FPGA's 3. The embodiment shown in FIGS. 1 and 2 uses serial advance technology attachment (SATA), but it should be understood that others may be used. The system interface 16 may be connected to an embedded processor within each FPGA 3. This processor will control the communication over the system. The system interface 16 integrates the control electronics 10 with the holographic storage system.

The control electronics 10 are also connected to the DDR memory 18 of the holographic storage system. The control electronics 10 are also connected to a clock generator 20.

The control electronics 10 may also send X and Y coordinate signals 63 to the DAC 22a and to a beam steering device 26. The beam steering device 26 may send X and Y feedback signals 71 to the ADC 24a and to control electronics 10.

The control electronics 10 additionally sends signals to the spatial light modulator 28, which is comprised of micro-mirrors 11. The control electronics 10 transmit write data signals 64 to the DLP chip set 27 then to the spatial light modulator 28. The spatial light modulator 28 may be a Digital Light Processor (DLP) or a Directly Modulated Spatial Light Modulator (DMSLM). The control electronics 10 additionally transmit row number signal 65 to the DLP chip set 27 then to the spatial light modulator 28. The control electronics 10 additionally transmit clock signals 66 to the DLP chip set 27 then to the spatial light modulator 28.

The control electronics 10 further sends signals to a shutter 30. The control electronics 10 transmit a read/write pulse signal 67 and write data signals 64 to the shutter 30. The control electronics 10 additionally transmit erase pulse signals 68 to the shutter 30. The control electronics 10 additionally transmit a pulse amplitude signal 69 to DAC 22b to the shutter 30.

Intensity sensors 32 transmit intensity signals 72 to the ADC 24b then to the control electronics 10.

FIG. 2 shows a block diagram of logic programs that comprise the control electronics 10. The various logic programs discussed herein are integrated control electronics that are connected to a system interface 16 and are adapted for controlling the various physical components of the holographic storage system. It should be understood that the logic programs are embodied in the circuitry that forms the control electronics. In the embodiment shown in FIGS. 1 and 2, control electronics 10 may comprise one or more field programmable gate arrays 3 (FPGA), wherein the logic programs discussed herein are programmed thereon.

The FPGAs 3 may perform the function of providing the system interface 16 that will connect the holographic storage system to either a host computer or a network.

Forward Error Correction (FEC) Decode Logic 320 and FEC Encode Logic 314 converts the data being placed into and taken out of the holographic storage system. FEC Encode Logic 314 operates on the data that is received from the system interface 16. FEC Decode Logic 320 operates on the data moving out of the holographic storage system.

The control electronics 10 may also have an Address Decode Logic 312 that decodes the address into a Page and Cluster location on a Page used in the holographic storage system. The Address Decode Logic 312 will take the address entered into the holographic storage system and convert it into page number and cluster information.

A Page Control logic 316 commands the Beam Steering device 26 so as to direct a reference beam to a particular point on a selected page for reading and writing to and from the photorefractive crystal used in the holographic storage system.

The control electronics 10 may also comprise Write Control Logic 310 which is used to encode the write data into the data beam used in the holographic storage system. The Write Control Logic 310 may take data received from the FEC Encode Logic 314, the Address Decode Logic 312 and the Erase Pattern Logic 318 and transmit that information to the Spatial Light Modulator (SLM) 28.

The control electronics 10 may also comprise Shutter Control Logic 328 so as to shutter the data and reference beams. This occurs so that the reference Beam may be phase shifted by 180° for implementing the erase function and allowing partial opening of each shutter 30 so as to allow the intensity of each beam to be controlled, and sensor monitors to monitor the intensity of each beam. The Shutter Control Logic 328 will receive beam intensity signals and transmit read/write pulses, erase pulses and data pulses to the shutter 30.

The control electronics 10 may also comprise Optical Sensor Array Interface 324 that will send control signals to the optical sensor array 14. The Optical Sensor Array Interface 324 will capture and format the pixels and send windows to the optical sensor array 14. The Optical Sensor Array Interface 324 will transmit this information to the Threshold Detector Logic 322 which then will assign the various pixel magnitudes to some binary code. This data is then transmitted to the FEC Decode Logic 320. In the case of binary data, there is one threshold per pixel, where a pixel is assigned the value of one or zero based on whether or not its intensity is above or below the threshold. In the grayscale case, there are several thresholds, each one of which is associated with a different number. The present embodiment may use the Cypress LUPA 1300-2. 10-bit pixels are downloaded in 12 serial data streams with a sync channel. The Optical Sensor Array Interface 324 then aligns the pixels. The pixels are then fed into the Threshold Detector Logic 322 where they are first converted into bits and then concatenated into bytes. For the initial system, there are 2 levels and 1 bit. For gray scale systems, 4 levels will be output as 2 bits; 16 levels as 4 bits, etc.

The control electronics 10 may also comprise the Command Sequencer 326 which receives commands from the system interface 16 and sends status to the system interface and further controls the other blocks.

The control electronics 10 may also comprise the Bulk Erase Control 330 that may send bulk erase signals to the bulk erase laser 7. The bulk erase laser 7 is used to erase the entire crystal.

The control electronics 10 may also comprise Laser Power Control Logic 332 so as to control the power of the Laser 9. The Laser Power Control Logic 332 may turn the Laser ON OFF or place it on Standby. The Laser Power Control Logic may also shutter the data path and the reference path.

There may also be Temperature Control Logic 334 that is used to monitor the temperature and control the Thermo-electric Coolers 4.

The control electronics 10 in FIGS. 1 and 2 is an ICE-BD single chip digital controller (SCDC). The control electronics 10 may be implemented as either an FPGA or an ASIC. An implementation may be as a Xilinx Virtex 5 FPGA combined with a Virtex 4 FPGA and may comprise an embedded processor as well as the control modules discussed above.

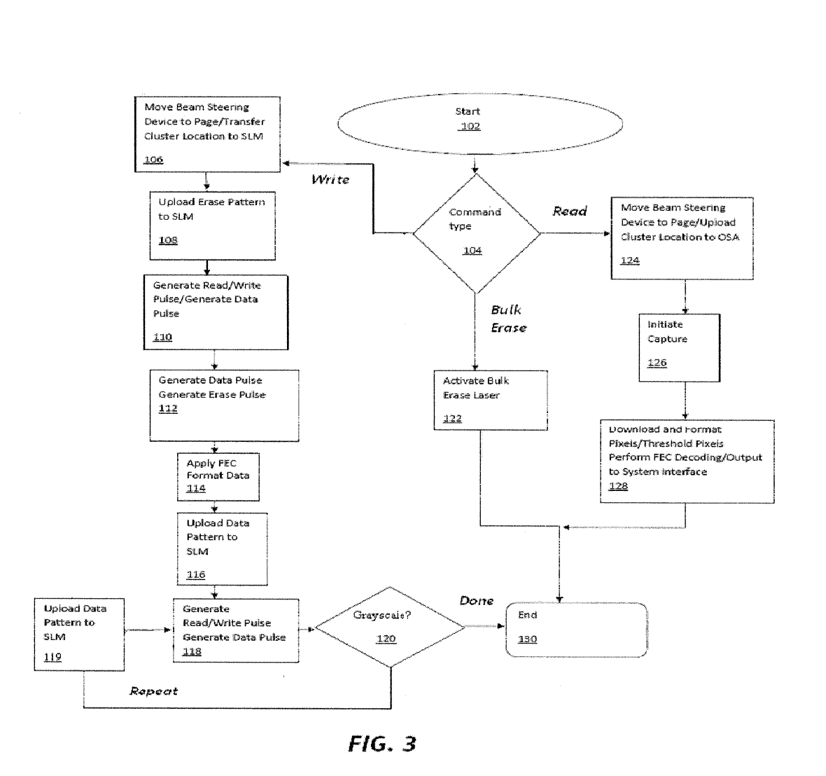

FIG. 3 is a flow chart showing the process for reading and writing within a holographic storage system.

At step 102, the system interface 16 receives commands and data to be written to the crystal from the Host Computer and sends it to the Command Sequencer 326 in the control electronics 10. The Command Sequencer 326 may comprise one or more embedded processors, stse machines, or some combination of these elements. The Command Sequencer 326 uses the system interface 16 to send status info and data read from the crystal to the Host Computer. As discussed above the system interface 16 is implemented as a SATA interface although it may be any high-speed interface used by bulk storage devices, such as USB, Firewire, SAS, Fiber Channel etc.

At step 104 the command type is determined and will move to step 106, step 122 or step 124. If the command type is for a read/write type of operation then it moves to step 106. At step 106 the beam steering device 26 is moved to the page/transfer cluster location and the Write Control Logic for the SLM 28.

At step 108 the erase pattern may be uploaded to the SLM 28. At step 110, a read/write pulse or a data pulse may be generated. At step 110, the pulse amplitudes are set and a read/write pulse or a data pulse may be generated. At step 112, the pulse amplitudes are set and a data pulse may be generated or an erase pulse may be generated. At step 114, the FEC Encode Logic 314 may be applied to format the data. At step 119, the data pattern may be uploaded to the SLM 28. At step 118, the pulse amplitudes are set and a read/write pulse or a data pulse may be generated.

At step 120, it is determined if grayscale is going to be used. If grayscale is going to be used then the pixels are written multiple times. Gray levels are determined by how many times a pixel is written to as a 1 or a 0. This may be repeated until needed and then the method moves to step 130. Grayscale Commands may be given in one of two ways. One method is to update the data pattern on the MEMS SLM 28 while the Read/Write Pulse and Data Pulse are still being asserted. Another optional method is to re-load the data pattern to the SLM 28 at step 119 after these pulses have finished asserting; then re-asserting them after the SLM 28 is re-loaded.

If the command type is for a bulk erase, at step 122 the bulk erase laser 7 is activated. This will erase the photorefractive crystal. The method then moves to the end at step 130.

If the command type is for capturing a data page, at step 124 the beam steering device 26 is move to the page/upload location via the optical sensor array 14. The capture of the page is initiated at step 126. At step 128, the pixels/threshold pixels are downloaded and FEC decoding is performed using the FEC Decode Logic 320, where any errors that were introduced in writing, storing or reading the data are removed. The data is then sent to the system interface 16. The method then moves to the end at step 130.

It is to be understood, however, that even though numerous characteristics and advantages of the present invention have been set forth in the foregoing description, together with details of the structure and function of the invention, the disclosure is illustrative only, and changes may be made in detail, especially in matters of shape, size and arrangement of parts within the principles of the invention to the full extent indicated by the broad general meaning of the terms in which the appended claims are expressed.

What is claimed is:

1. Integrated control electronics for a holographic storage system comprising:
a Command Sequencer for receiving commands from a system interface;
a Write Control Logic for encoding write data into a data beam;
a Page Control Logic for controlling a beam steering device for directing a reference beam; and
an Optical Sensor Array Interface for sending control signals to an optical sensor array.

2. The integrated control electronics of claim 1, further comprising Forward Error Correcting Encode Logic.

3. The integrated control electronics of claim 2, further comprising Forward Error Correcting Decode Logic.

4. The integrated control electronics of claim 1, wherein the Optical Sensor Array Interface transmits pixel data to Threshold Detector Logic.

5. The integrated control electronics of claim 1, further comprising Shutter Control Logic for controlling a shutter.

6. The integrated control electronics of claim 1, further comprising Laser Power Control Logic for controlling a laser.

7. The integrated control electronics of claim 1, wherein the Write Control Logic controls a Spatial Light Modulator (SLM).

8. The integrated control electronics of claim 1, further comprising Bulk Erase Control Logic for controlling a bulk erase laser.

9. The integrated control electronics of claim 1, further comprising Temperature Control Logic for controlling the thermo-electric coolers.

10. The integrated control electronics of claim 1, further comprising one or more field programmable gate arrays having the Command Sequencer; the Write Control Logic; the Page Control Logic and the Optical Sensor Array Interface programmed thereon.

11. A method for using integrated control electronics in a holographic storage system comprising the steps of:
receiving commands via a system interface at a command sequencer;
operating a beam steering device using Page Control Logic;
operating a spatial light modulator using Write Control Logic;
operating an Optical Sensor Array Interface for sending control signals to an optical sensor array; and
wherein data is written to and read from a photorefractive crystal using the steps of operating the beam steering device; operating the spatial light modulator and operating the optical sensor array.

12. The method of claim 11, further comprising providing Forward Error Correcting Encode Logic.

13. The method of claim 11, further comprising providing Forward Error Correcting Decode Logic.

14. The method of claim 11, further comprising transmitting pixel data to a Threshold Detector Logic.

15. The method of claim 11, further comprising controlling a shutter using Shutter Control Logic.

16. The method of claim 11, further comprising controlling a laser using Laser Power Control Logic.

17. The method of claim 11, further comprising bulk erasing a photorefractive crystal using Bulk Erase Control Logic for controlling a bulk erase laser.

18. The method of claim 11, further comprising controlling thermo-electric coolers using Temperature Control Logic.

19. The method of claim 11, wherein the data is written to and read from the photorefractive crystal using grayscale.

20. Integrated control electronics for a holographic storage system comprising:
a field programmable gate array is adapted for providing Write Control Logic for encoding write data into a data beam;
wherein the field programmable gate array is programmed to provide a Command Sequencer for receiving commands from a system interface;
wherein the field programmable gate array is programmed to provide Write Control Logic for encoding write data into a data beam;
wherein the field programmable gate array is programmed to provide Page Control Logic for controlling a beam steering device for directing a reference beam; and
wherein the field programmable gate array is programmed to provide an Optical Sensor Array Interface for sending control signals to an optical sensor array.
